(19) United States
(12) Patent Application Publication
(10) Pub. No.: US 2007/0053419 A1
(43) Pub. Date: Mar. 8, 2007

(54) Adaptive analog equalizer and digital signal receiver having the same

(76) Inventors: Sung Kyung Park, Yuseong-gu (KR); Sang Jin Byun, Yuseong-gu (KR); Hyun Kyu Yu, Yuseong-gu (KR)

Correspondence Address: LADAS & PARRY LLP, 224 SOUTH MICHIGAN AVENUE, SUITE 1600, CHICAGO, IL, 60604, US

(21) Appl. No.: 11/434,489

(22) Filed: May 15, 2006

(30) Foreign Application Priority Data
Sep. 2, 2005 (KR) 10-2005-0081900

(51) Int. Cl. H03H 7/30

(52) U.S. Cl. 375/232

(57) ABSTRACT

Provided are an adaptive analog equalizer and a digital signal receiver having the same. The adaptive analog equalizer includes selective comparing means for comparing the data equalized by the equalizing means to an internal reference value set based on the equalized data to output an error signal e(n); sign inverting means for selecting one of the selective comparing means; and a tap coefficient generating means for accumulating the error signal outputted from the selective comparing means and recognizing the intersymbol interference varying with time to generate an adaptive tap coefficient.

### CROSS-REFERENCE TO RELATED APPLICATION

This application claims priority to and the benefit of Korean Patent Application No. 2005-81900, filed on Sep. 2, 2005, the disclosure of which is incorporated herein by reference in its entirety.

### BACKGROUND

1. Field of the Invention

The present invention relates to an equalizer for restoring a distorted signal in a digital signal receiver and, more particularly, to an adaptive analog equalizer having an analog circuit which employs a least means square (LMS) algorithm, and a digital signal receiver having the same.

2. Discussion of Related Art

A digital signal receiver usually undergoes the intersymbol interference (ISI) due to limited bandwidth, distortion and dispersion of a channel when data is transmitted via a channel at a high speed of more than Giga bit per second (Gbps). Here, the channel refers to as a wire line such as an optical fiber cable, a high speed serial/parallel link, a printed circuit board (PCB) trace, a coaxial cable and a twisted pair line.

The intersymbol interference is a main factor that distorts the transmitted signal and causes bit errors in the receiver. Besides, the intersymbol interference has been recognized as a main fail factor in transmitting data at a high speed via a multi-path channel.

The receiver performs signal processing using an equalizer to minimize the intersymbol interference and restore the distorted data signal.

A typical communication channel has a feature varying with time, and so the equalizer should have a capability of tracking a time-varying characteristic of the channel. The equalizer considering such a time-varying characteristic of the channel is called a time-domain adaptive equalizer.

If the intersymbol interference varies in the time domain as the polarization-mode dispersion of the cable slowly varies with a time in an optical communication which transmits information via an optical fiber, a filter tap weight factor of the equalizer needs to be adjusted in the time domain to continuously minimize the intersymbol interference.

The time-domain adaptive equalizer employs a least mean square (LMS) algorithm which is easy to implement and excellent in performance.

Using the LMS algorithm, an adaptive tap coefficient “c(n+1)” can be calculated by Equation 1:
c(n+1)=c(n)+μ×e(n)×x(n) Equation 1

where c(n) denotes a tap coefficient at a time n, μ denotes a step size, e(n) denotes an error signal, and x(n) denotes a signal before being equalized at a time n.

As described above, the time-domain adaptive equalizer operates in the time domain and employs the LMS algorithm which has a less amount of computation in updating coefficients, thereby being simple to implement even with a low convergence speed.

FIG. 1 is a block diagram of a conventional digital signal receiver having a time-domain adaptive equalizer.

Referring to FIG. 1, the digital signal receiver includes a multi-channel analog-digital converter (ADC) 100 for converting an analog signal outputted from a variable gain amplifier which adjusts an amplitude of an input signal into a digital signal, a temporal-rearranging portion 200 for equalizing the digital signal outputted from the multi-channel ADC 100, an adaptive equalizer 300 and 400 for compensating amplitude distortion or phase distortion of the equalized signal in the digital domain using an appropriate tap coefficient corresponding to the intersymbol interference which may vary with a time, and a system interface for transferring the signal outputted from the adaptive equalizer 300 and 400 to a specific system.

FIG. 2 is a detailed diagram of a conventional adaptive equalizer. The adaptive equalizer of FIG. 2 includes an equalizer 300 and an adapting unit 400.

Referring to FIG. 2, the adapting unit 400 compensates the channel while adaptively equalizing a distorted transmission channel using the LMS algorithm with any initial coefficient. The equalizer 300 removes or mitigates the intersymbol interference of the time-domain output data adapted by the adapting unit 400.

The equalizer 300 includes a plurality of delays 310, amplifiers 320 which performs amplification while updating the filter tap coefficients with the LMS algorithm by using values delayed by the number of the delays 310, and an adder 330 for adding the filter tap coefficients.

Operation of the conventional time-domain adaptive equalizer will be described in detail with reference to the accompanying drawings.

FIGS. 3(a) to 3(d) show the intersymbol interference caused by one bit and a procedure for equalizing it by the time-domain adaptive equalizer according to the conventional art. Here, it is assumed that the intersymbol interference is caused by one bit for convenience of description.

Referring to FIGS. 3(a) to 3(d), if the intersymbol interference occurs that an input bit inputted at a receiving side affects a current bit, a data wave is distorted like a received signal X(t) of FIG. 3(a).

If a data string “001011” is received from a transmitting side, a pulse corresponding to a third bit “1” of the received signal string which has undergone the intersymbol interference is not sufficiently raised due to affection by a previous bit “0.” Similarly, a pulse corresponding to a fourth bit “0” of the received signal string does not sufficiently descend.

Thus, the receiving side should perform an equalization procedure to sufficiently raise a pulse of a subsequent bit “1” even with the previous bit of “0” and to make the current bit “0” sufficient drop even with the previous bit of “1.”

The equalization procedure will be now explained in detail. Here, it is assumed that the equalizer of FIG. 2 is a feed-forward equalizer.

If the distorted received signal X(t) of FIG. 3(a) is received, the distorted received signal X(t) is delayed by one bit by the delay 310 to get the delayed signal X(t−T) of FIG. 3(b).

The delayed signal X(t−T) is amplified by −C1 times by the amplifier 320 to get an amplified signal −C1×X(t−T) of FIG. 3(c). Here, C1 has a positive value.

Since the equalizer is the feed-forward equalizer having one delay element, a final wave X(t)−C1×X(t−T) of FIG. 3(d) is outputted from the adder 330 of the equalizer.

As described above, the distorted received signal has a bit “1” and a bit “0” clearly identified through the equalizer 300.

However, the adaptive equalizer of FIG. 1 has high functional flexibility due to its operation in the digital domain, but has a problem in that a chip area size and power consumption increase compared to its operation in the analog domain due to the added ADC 100 and the temporal rearranging portion 200.

To solve the aforementioned problem, an equalizer in which an analog equalizer is employed to directly perform equalization in the analog domain and the adapting unit is modified as shown in FIG. 4 has been introduced. That is, the equalizer having the adapting unit of FIG. 4 does not include the ADC 100 and the temporal rearranging portion 200 of FIG. 1.

The adapting unit 400 of FIG. 4 is employed in an adaptive analog filter and includes a decision portion 410, a first squarer 420, a second squarer 430, and an accumulator 440. The first and second squarers 420 and 430 square input and output signals of the decision portion 410 to measure amplitudes of the input and output signals of the decision portion 410. The accumulator 440 receives the amplitude information of the input and output signals of the decision portion 410 outputted from the first and second squarers 420 and 430 to accumulate a difference between the input and output signals and adjusts a tap coefficient using the accumulation result.

Here, a result value resulting from a difference between the first and second squarers 420 and 430 represents an error caused from the intersymbol interference.

However, since the adapting unit of FIG. 4 includes the first and second squarers 420 and 430, it is difficult to say that a problem of the adaptive equalizer of FIG. 1 such as the large chip area size and high power consumption has been resolved. In addition, the adaptive equalizer having the adapting unit of FIG. 4 will have performance degradation compared to the adaptive equalizer of FIG. 1 using the LMS algorithm.

### SUMMARY OF THE INVENTION

The present invention is directed to an adaptive analog equalizer in which channel distortion is minimized by compensating signal distortion and dispersion and maintaining a received signal wave optimal by using an equalizer and an adapting unit of an analog domain, and a digital signal receiver having the same.

The present invention is also directed to an adaptive analog equalizer in which a chip area size and power consumption are reduced and high performance is achieved using a modified LMS algorithm, and a digital signal receiver having the same.

One aspect of the present invention is to provide an adaptive analog equalizer including: an equalizing means for equalizing an intersymbol interference (ISI); and an adapting means for generating an adaptive tap coefficient “c(n+1)” to compensate, in a time domain, the intersymbol interference varying with time when equalizing the intersymbol interference by using Equation: c(n+1)=c(n)+μ×e(n)×s(n), where c(n) denotes a tap coefficient at a time n, μ denotes a step size, e(n) denotes an error signal, and s(n) denotes a signal of data which is equalized at a time n.

Preferably, the adapting means may include: selective comparing means for comparing the data equalized by the equalizing means to an internal reference value set based on the equalized data to output an error signal e(n); sign inverting means for selecting one of the selective comparing means; and a tap coefficient generating means for accumulating the error signal outputted from the selective comparing means and recognizing the intersymbol interference varying with time to generate an adaptive tap coefficient.

Preferably, the adaptive analog equalizer may further include a signal converting means disposed between the selective comparing means and the tap coefficient means for converting a voltage signal which is the error signal outputted from the selective comparing means to an electric current signal.

Preferably, the internal reference value may be generated and stored in advance with reference to a bit rate of a low level 0 and a high level 1, and a sign of the equalized data may be defined by either a low level 0 or a high level 1 by comparing the data equalized by the equalizing means to the previously stored reference value.

Preferably, the adapting means may include: a first comparing means for comparing waveform of an analog signal equalized by the equalizing means to that of logical value 1 (high level) and detecting an error signal by the waveform difference; a second comparing means for comparing waveform of an analog signal equalized by the equalizing means to that of logical value 0 (low level) and detecting an error signal by the waveform difference; a sign inverting means for selecting and operating one of first and second comparing means according to a sign of the equalized data defined through the analog signal equalized by the equalizing means; a signal converting means for converting an output signal of one of the first and second comparing means selected by the signal inverting means to an electric current signal; and a tap coefficient generating means for accumulating the electric current signal converted by the signal converting means as electric charges in an integrator and recognizing the intersymbol interference varying with time from the difference of the accumulated electric charges to generate an adaptive tap coefficient

Preferably, the sign of the equalized data may be defined as “1” if the equalized analog signal is determined to be “1” and defined as “0” if the equalized analog signal is determined to be “0.”

Another aspect of the present invention is to provide a digital signal receiver including: an adaptive analog equalizer according to the present invention for compensating, in a time domain, an intersymbol interference of a transmission channel outputted as an analog signal from a variable gain amplifier for maintaining amplitude of an input signal constant; and a system interface for transferring a signal outputted from the adaptive analog equalizer to a specific system.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a block diagram of a conventional digital signal receiver having a time-domain adaptive equalizer.

FIG. 2 is a detailed diagram of a conventional adaptive equalizer.

FIGS. 3(a) to 3(d) show the intersymbol interference caused by one bit and a procedure for equalizing it by the time-domain adaptive equalizer according to a conventional art.

FIG. 4 is a block diagram of a conventional modified adapting unit.

FIG. 5 is a block diagram of a digital signal receiver having an adaptive analog equalizer according to the present invention.

FIG. 6 is a circuit diagram of an adapting unit of the adaptive analog equalizer according to the present invention.

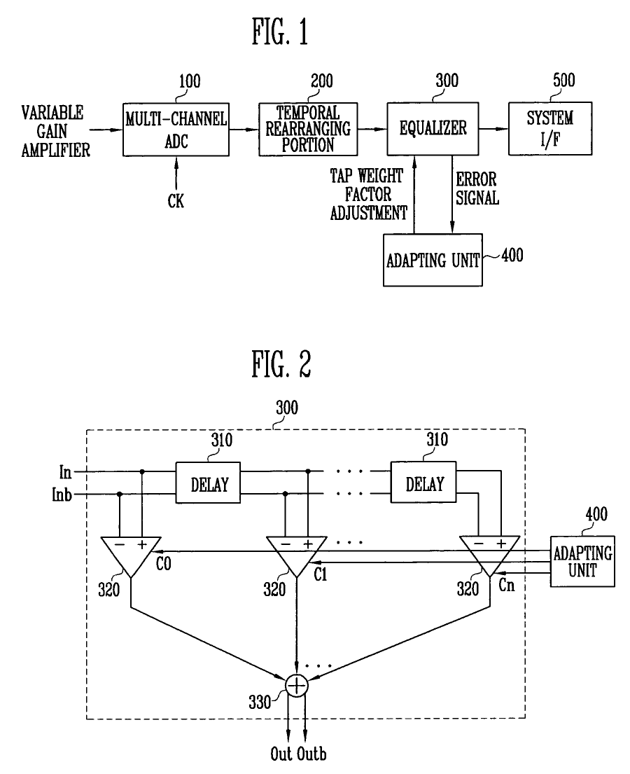

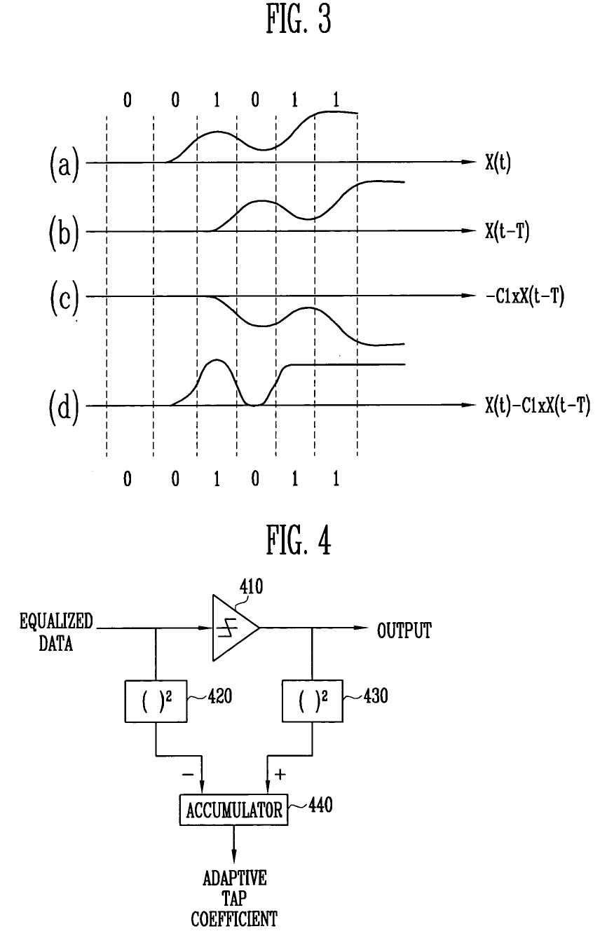

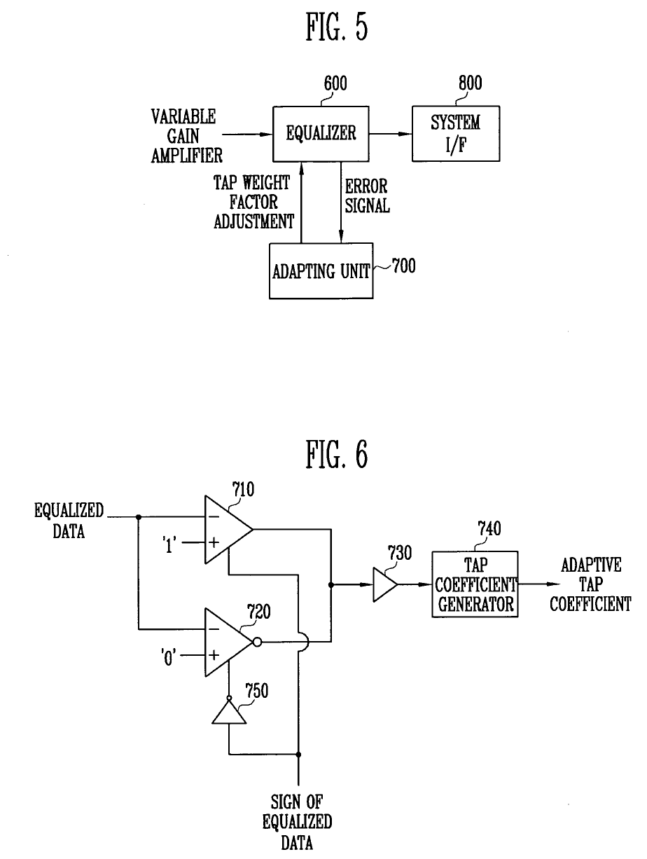

### DETAILED DESCRIPTION OF PREFERRED EMBODIMENTS

Hereinafter, an exemplary embodiment of the present invention will be described in detail. However, the present invention is not limited to the embodiments disclosed below, but can be implemented in various types. Therefore, the present embodiment is provided for complete disclosure of the present invention and to fully inform the scope of the present invention to those ordinarily skilled in the art.

FIG. 5 is a block diagram briefly illustrating the configuration of a digital signal receiver having an adaptive analog equalizer according to the present invention. FIG. 6 is a circuit diagram of an adapting unit of an adaptive analog equalizer according to the present invention.

Referring to FIG. 5, the digital signal receiver includes an adapting unit 700 for compensating, with any initial coefficient, a channel by adaptively equalizing a distorted transmission channel outputted as an analog signal from a variable gain amplifier, which adjusts the amplitude of an input signal, using the LMS algorithm; an equalizer 600 for estimating and removing intersymbol interference within the analog signal inputted from the variable gain amplifier by using an appropriate tap coefficient corresponding to the intersymbol interference which may vary with time, from the adapting unit 700; and a system interface 800 for transferring the signal from the equalizer 600 to a specific system.

The adapting unit 700 includes selective comparators 710 and 720, which compare data equalized by the equalizer 600 to a reference value which is set based on the equalized data to output an error signal e(n); a sign inverter 750 which selects one of the selective comparators 710 and 720; and a tap coefficient generator 740 which continuously reduces the intersymbol interference which varies with time while accumulating an error signal outputted from the one of the selective comparators 710 and 720.

The error signals outputted from the selective comparators 710 and 720 are voltage signals. In order to convert the voltage signal into an electric current signal, which can be used in the tap coefficient generator 740, a signal converter 730 is added between the selective comparators 710 and 720 and the tap coefficient generator 740.

FIG. 6 shows a circuit diagram of the adapting unit 700 having the above-described function. A circuitry structure as shown in FIG. 6 can be represented by Equation 2, which will be explained below.

Referring to FIG. 6, a first comparator 710 compares the analog signal equalized by the equalizer 600 to logical value 1 (i.e., high level) and detects an error signal by the difference between them. A second comparator 720 compares the analog signal equalized by the equalizer 600 to logical value 0 (i.e., low level) and detects an error signal by the difference between them. A sign inverter 750 controls one of the first and second comparators 710 and 720 to operate according to a reference value, which is set based on the analog signal equalized by the equalizer 600. A signal converter 730 converts an output signal of the first comparator 710 or that of the second comparator 720, which can be selected by the sign converter 750, into an electric current signal. A tap coefficient generator 740 accumulates the electric current signal as electric charges and recognizes the intersymbol interference varying with time, using the difference between the accumulated electric charges, to thereby generate an adaptive tap coefficient.

Preferably, the sign inverter 750 is composed of an inverter, the signal converter 730 is composed of a transconductor, and the tap coefficient generator 740 is composed of an integrator or a capacitor.

The equalizer 600 has the same structure as used in the conventional art. Preferably, the equalizer 600 may include a plurality of delays 310, amplifiers 320 for performing amplification while updating a filter tap coefficients with the LMS algorithm by using values delayed by the number of the delays 310, and an adder 330 for adding the filter tap coefficients, as shown in FIG. 2.

Operation of the digital signal receiver having the adaptive analog equalizer according to the present invention will be explained in detail with reference to the accompanying drawings.

Referring to FIG. 6, the first comparator 710 detects a difference between the data equalized by the equalizer 600 and logical value 1 (i.e., high level), and the first comparator 720 detects a difference between the data equalized by the equalizer 600 and logical value 0 (i.e., low level).

At this time, only one of the first and second comparators 710 and 720 operates by selection of the sign inverter 750 using a sign of the equalized data to be defined through the equalized data.

In other words, a sign of the equalized data is defined by the equalized data. For example, a sign of the equalized data is defined as “1” if the equalized data is determined to be “1,” whereas the sign of the equalized data is defined as “0” if the equalized data is determined to be “0”. Here, it is assumed that the intersymbol interference is not so large to the extent that signal inversion occurs.

As described above, the sign inverter 750 using a sign of the equalized data activates the first comparator 710 but not the second comparator 720 if the sign of the equalized data is “1,” so that only the first comparator 710 operates.

On the contrary, the sign inverter 750 activates the second comparator 720 but not the first comparator 710 if the sign of the equalized data is “0,” so that only the second comparator 720 operates.

Thus, the obtained voltage output of the first comparator 710 or the second comparator 720 is converted to an electric current signal by the signal converter 730, the electric current signal being charged as electric charges in the tap coefficient generator 740. The tap coefficient generator 740 recognizes the intersymbol interference varying with time from the difference of the accumulated electric charges to generate the adaptive tap coefficient.

While the adapting unit 700 may be designed so that the sign of the equalized data is used to minimize an error, i.e., a difference between an output from a identifying circuit for periodically identifying a signal of 0 or 1 in synchronization with a clock signal and the equalized data, the adapting unit 700 herein has a reference value that is generated and stored in the adapting unit 700 in advance, the reference value being based on a bit level of 0 or 1. The adapting unit 700 is designed so that the sign of the equalized data is defined as “0” or “1” through the comparison between the inputted equalized data and the previously stored reference value.

Using a sign-data LMS algorithm modified from Equation 1 under the assumption that the intersymbol interference is not as large as signal inversion occurs, a tap coefficient c(n+1) is calculated by Equation 2:
c(n+1)=c(n)+μ×e(n)×s(n) Equation 2

where s(n) denotes a signal of data which is equalized at a time n.

In Equation 2, the step size μ is determined by a gain of the comparator, a gain of the signal converter, and a size of the tap coefficient generator. Since variation with time of dispersion and distortion is slow compared to a bit rate of data in most cases, the tap coefficient “c(n+1)” can be properly calculated with a small step size μ.

In Equation 2, e(n) denotes an error signal corresponding to a difference between a logical level “0” or “1” and the equalized data.

Equation 2 is implemented by the adapting unit of FIG. 6.

That is, the adapting unit of FIG. 6 includes the first and second comparators 710 and 720 for detecting the error signal, the sign inverter 750 for operating only one of the first and second comparators 710 and 720 based on a predetermined internal reference value, the signal converter 730 comprised of the transconductor for converting the output signal of the selected one of the first and second comparators 710 and 720 to the electric current signal, and the tap coefficient generator 740 for accumulating the electric current signal as electric charges and recognizing the intersymbol interference varying with time from a difference between the accumulated electric charges, to thereby generate an adaptive tap coefficient.

In the way described above, the adapting unit 700 adaptively adjusts each tap coefficient of the equalizer 600.

The equalizer 600 estimates and removes the intersymbol interference within the analog signal inputted from the variable gain amplifier by using the tap coefficient adaptively adjusted by the adapting unit 700. The signal outputted from the equalizer 600 is then transferred to the specific system through the system interface 800.

As described above, the adaptive analog equalizer and the digital signal receiver having the same according the present invention have the following advantages:

First, any data converter is not required due to processing of analog data. Thus, it is possible to implement an adaptive analog equalizer with low power consumption and low manufacture cost, and the digital signal receiver having the same.

Second, it is possible to implement a high performance adaptive analog equalizer by adopting a modified LMS algorithm and implementing the algorithm in a circuitry manner for processing in an analog domain.

Third, it is possible to minimize channel distortion in the digital signal receiver by compensating signal distortion and dispersion and maintaining a received waveform optimal using the equalizer and the adapting unit for the analog domain.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An adaptive analog equalizer, comprising:
equalizing means for equalizing an intersymbol interference (ISI); and
adapting means for generating an adaptive tap coefficient “c(n+1)” by using the following equation to compensate, in a time domain, the intersymbol interference varying with time in the equalization by the equalizing means.
c(n+1)=c(n)+μ×e(n)×s(n),
where c(n) denotes a tap coefficient at time n, μ denotes a step size, e(n) denotes an error signal, and s(n) denotes a sign of data which is equalized at a time n.

2. The adaptive analog equalizer of claim 1, wherein the adapting means includes:
selective comparing means for comparing the data equalized by the equalizing means to an internal reference value set based on the equalized data to output an error signal e(n);
sign inverting means for selecting one of the selective comparing means; and
a tap coefficient generating means for generating an adaptive tap coefficient by recognizing the intersymbol interference varying with time while accumulating the error signal from the selective comparing means.

3. The adaptive analog equalizer of claim 2, further comprising signal converting means disposed between the selective comparing means and the tap coefficient means for converting a voltage signal which is the error signal outputted from the selective comparing means to an electric current signal.

4. The adaptive analog equalizer of claim 2, wherein the internal reference value is generated and stored internally in advance based on a bit rate of a low level 0 and a high level 1, a sign of the equalized data being defined by either a low level 0 or a high level 1 through comparison between the data equalized by the equalizing means and a previously stored reference value.

5. The adaptive analog equalizer of claim 1, wherein the adapting means includes:
first comparing means for comparing waveform of an analog signal equalized by the equalizing means to that of logical value 1 (high level) and detecting an error signal by the waveform difference;
second comparing means for comparing waveform of the analog signal equalized by the equalizing means to that of logical value 0 (low level) and detecting an error signal by the waveform difference;
sign inverting means for controlling one of first and second comparing means to operate according to a sign of the equalized data defined through the analog signal equalized by the equalizing means;
signal converting means for converting an output signal of the one of the first and second comparing means selected by the signal inverting means to an electric current signal; and
tap coefficient generating means for accumulating the electric current signal converted by the signal converting means as electric charges in an integrator and recognizing the intersymbol interference varying with time from the difference of the accumulated electric charges to generate an adaptive tap coefficient.

6. The adaptive analog equalizer of claim 5, wherein the sign of the equalized data is defined as “1” if the equalized analog signal is determined to be “1” and is defined to be “0” if the equalized analog signal is determined to be “0”.

7. A digital signal receiver, comprising:
an adaptive analog equalizer of any of claims 1 to 6 for compensating, in a time domain, an intersymbol interference of a transmission channel outputted as an analog signal from a variable gain amplifier for maintaining the amplitude of an input signal constant; and
a system interface for transferring a signal outputted from the adaptive analog equalizer to a specific system.
